(19) United States
(12) Patent Application Publication
(10) Pub. No.: US 2001/0033476 A1
(43) Pub. Date: Oct. 25, 2001

(54) Thermal/mechanical springbeam mechanism for heat transfer from heat source to heat dissipating device

(76) Inventors: Joseph T. Dibene II, Oceanside, CA (US); David H. Hartke, Durango, CO (US); Wendell C. Johnson, Long Beach, CA (US); Edward J. Derian, San Diego, CA (US)

Correspondence Address: GATES & COOPER LLP, HOWARD HUGHES CENTER, 6701 CENTER DRIVE WEST, SUITE 1050, LOS ANGELES, CA, 90045, US

(21) Appl. No.: 09/798,541

(22) Filed: Mar. 2, 2001

Related U.S. Application Data
(63) Continuation-in-part of application No. 09/353,428, filed on Jul. 15, 1999.
(63) Continuation-in-part of application No. 09/432,878, filed on Nov. 2, 1999.
(63) Continuation-in-part of application No. 09/727,016, filed on Nov. 28, 2000.
(60) Provisional application No. 60/186,769, filed on Mar. 3, 2000.
(60) Provisional application No. 60/183,474, filed on Feb. 18, 2000.
(60) Provisional application No. 60/187,777, filed on Mar. 8, 2000.
(60) Provisional application No. 60/196,059, filed on Apr. 10, 2000.
(60) Provisional application No. 60/219,813, filed on Jul. 21, 2000.
(60) Provisional application No. 60/232,971, filed on Sep. 14, 2000.
(60) Provisional application No. 60/251,222, filed on Dec. 4, 2000.
(60) Provisional application No. 60/251,223, filed on Dec. 4, 2000.
(60) Provisional application No. 60/251,184, filed on Dec. 4, 2000.

(51) Int. Cl. H05K 7/20

(52) U.S. Cl. 361/702

(57) ABSTRACT

A method, apparatus, and article of manufacture for transferring heat is disclosed. The apparatus comprises a first thermally conductive plate; a second thermally conductive plate; and an angularly corrugated member disposed between and in thermal communication first thermally conductive plate and the second thermally conductive plate. The angularly corrugated member has a contiguous periodically repeating cross section which includes a first cross section segment, disposable substantially parallel to and in thermal communication with the first thermally conductive plate, a second cross section segment, disposable substantially parallel to and in thermal communication with the second thermally conductive plate, and a third cross section segment, communicatively coupled to the first surface and the second surface, wherein the third cross section segment forming an angle with the first thermally conductive plate.

### CROSS-REFERENCE TO RELATED APPLICATIONS

This application claims benefit of the following U.S. Provisional patent applications, each of which are incorporated by reference herein:

Application Ser. No. 06/186,769, entitled “THERMACEP SPRING BEAM,” by Joseph T. DiBene II et al., filed Mar. 3, 2000;

Application Ser. No. 60/183,474, entitled “DIRECT ATTACH POWER/THERMAL WITH INCEP TECHNOLOGY,” by Joseph T. DiBene II and David H. Hartke, filed Feb. 18, 2000;

Application Ser. No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Ser. No. 60/196,059, entitled “EMI FRAME WITH POWER FEEDTHROUGHS AND THERMAL INTERFACE MATERIAL IN AN AGGREGATE DIAMOND MIXTURE,” by Joseph T. DiBene II and David H. Hartke, filed Apr. 10, 2000;

Application Ser. No. 60/219,813, entitled “HIGH CURRENT MICROPROCESSOR POWER DELIVERY SYSTEMS,” by Joseph T. DiBene II, filed Jul. 21, 2000; and

Application Ser. No. 60/232,971, entitled “INTEGRATED POWER DISTRIBUTION AND SEMICONDUCTOR PACKAGE,” by Joseph T. DiBene II and James J. Hjerpe, filed Sep. 14, 2000.

Application Ser. No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Ser. No. 60/251,223, entitled “MICRO-I-PAK FOR POWER DELIVERY TO MICROELECTRONICS,” by Joseph T. DiBene II and Carl E. Hoge, filed Dec. 4, 2000; and

Application Ser. No. 60/251,184, entitled “MICROPROCESSOR INTEGRATED PACKAGING,” by Joseph T. DiBene II, filed Dec. 4, 2000.

This patent application is also continuation-in-part of the following co-pending and commonly assigned patent applications, each of which applications are hereby incorporated by reference herein:

Application Ser. No. 09/353,428, entitled “INTER-CIRCUIT ENCAPSULATED PACKAGING,” by Joseph T. DiBene II and David H. Hartke, filed Jul. 15, 1999;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999;

Application Ser. No. 09/727,016, entitled “EMI CONTAINMENT USING INTERCIRCUIT ENCAPSULATED PACKAGING TECHNOLOGY” by Joseph T. DiBene II and David Hartke, filed Nov. 28, 2000; and

Application Ser. No. __/___,___, entitled “DIRECT ATTACH POWER/THERMAL WITH INCEP TECHNOLOGY,” by Joseph T. DiBene II, David H. Hartke, James J. Hjerpe Kaskade, and Carl E. Hoge, filed Feb. 16, 2001.

### BACKGROUND OF THE INVENTION

1. Field of the Invention

The present invention relates to systems and methods for dissipating heat from electronic components and similar devices, and specifically to a thermal mechanical construction for managing heat transfer between thermal loads and sources.

2. Description of the Related Art

As described in the co-pending and commonly assigned patent applications described above, stackup construction techniques have some particular advantages in the areas of electromagnetic interference control, thermal dissipation, and power delivery. However, one problem with the stackup construction technique is that it can present difficulties conducting heat from the component to the heat dissipating device. This is because assembly tolerances may create gaps between the elements of the stackup assembly, particularly the component and the heat dissipating device. Further, the dimension of such gaps can change with time, and with temperature. Such spaces can be filled with thermally conductive grease. However, this solution is not appropriate when the gap is too large, or where high thermal conductivity (low thermal resistance) is required.

There is a need for a highly thermally conductive interface which is also sufficiently compliant to accommodate a wide range of gaps and tolerance variations between the component and the heat dissipation device. The present invention satisfies that need.

### SUMMARY OF THE INVENTION

To address the requirements described above, the present invention discloses a method, apparatus, article of manufacture, and a memory structure for conducting heat from one or more components having non-coplanar surfaces to a heat dissipating device.

The apparatus comprises a first thermally conductive plate; a second thermally conductive plate; and an angularly corrugated member disposed between and in thermal communication with the first thermally conductive plate and the second thermally conductive plate. The angularly corrugated member has a contiguous periodically repeating cross section which includes a first cross section segment, disposable substantially parallel to and in thermal communication with the first thermally conductive plate, a second cross section segment, disposable substantially parallel to and in thermal communication with the second thermally conductive plate, and a third cross section segment, communicatively coupled to the first surface and the second surface, wherein the third cross section segment forming an angle with the first thermally conductive plate.

The foregoing provides a structure for managing the flow of heat from a heat source such as an electronic device to a heat load such as a heat sink using a thermal-mechanical spring beam construction. The spring beam construction manages the thermal path between a device and heat load with improved thermal conductivity (decreased thermal resistance) and easier assembly when compared with standard materials such as greases and elastomers. The corrugated mechanical spring fills the gaps created by assembly tolerances and stackup thickness differences while using the conductivity of the metallic (often copper) spring and base as an efficient thermal conduction path. The mechanical spring beam may be used in conjunction with elastomers and/or greases the plates and/or on the outer surfaces of the plates to ensure a heat conduction path from the component to the heat load with low thermal resistance.

### BRIEF DESCRIPTION OF THE DRAWINGS

Referring now to the drawings in which like reference numbers represent corresponding parts throughout:

FIG. 1 is a diagram showing a section view of a stackup assembly;

FIGS. 2A and 2B are diagrams showing a section view of spring beam construction in an uncompressed and compressed mode;

FIG. 3 is a diagram showing a section view of an assembly using the spring beam for thermal management;

FIG. 4 is a diagram showing an additional view of a single beam illustrating a higher conductive construction with lower beam strength to reduce stresses on the device;

FIG. 5 is a flow chart depicting exemplary method steps that can be used to assemble the heat transfer device; and

FIG. 6 is a flow chart depicting exemplary method steps used to practice a further embodiment of the invention.

### DETAILED DESCRIPTION OF PREFERRED EMBODIMENTS

In the following description, reference is made to the accompanying drawings which form a part hereof, and which is shown, by way of illustration, several embodiments of the present invention. It is understood that other embodiments may be utilized and structural changes may be made without departing from the scope of the present invention.

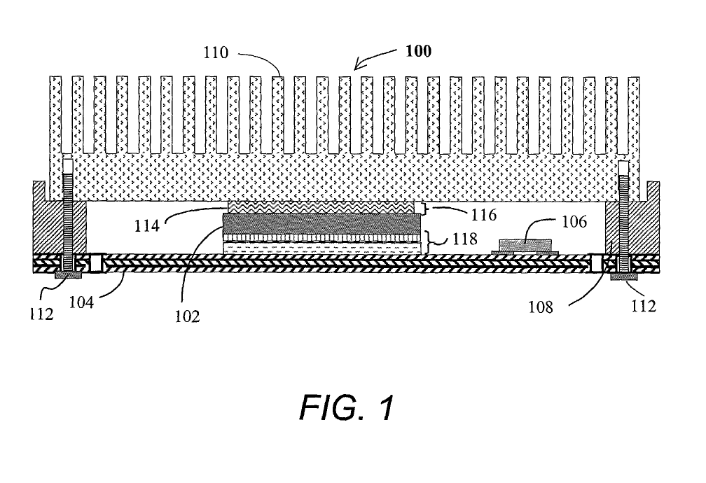

FIG. 1 is a diagram showing a section view of a stackup assembly 100. The stackup assembly 100 comprises an heat source such as an integrated circuit device 102 mounted to and in electrical communication with a printed circuit board 104. The printed circuit board 104 may also include other components 106 mounted thereon. A frame structure 108 circumscribing the integrated circuit device 102 may be used. The frame structure 108 supports a heat dissipating device such as a heat sink 110, which is mechanically mounted above the integrated circuit device 102. The heat sink 110 may be mounted on the frame 108 and secured by screws 112 or other fastening devices. One purpose of this frame 108 is to bear the weight of the heat sink 110, to prevent excessive weight from being applied to the integrated circuit device 102. To provide a path for thermal energy from the integrated circuit device 102 to the heat sink 110, a thermal interface material 114 may be placed between the integrated circuit device 102 and heat sink 110 for thermal conduction purposes.

The forgoing construction typically results in a gap 116 between the integrated circuit device 102 and the heat sink 110. This gap 116 can result because of assembly tolerances for the frame 108, the printed circuit board 104 and/or the integrated circuit device 102 and the communication elements 118 connecting that device with the printed circuit board 104. Or, this gap 116 can result because it is economically impractical to fashion a frame assembly 108 of precisely the proper dimension in the z-axis to assure that the integrated circuit device 102 physically contacts the heat sink 110. Further, it should be noted that the spacing between the elements of the stackup assembly 100 will not remain constant, but will change with time, temperature, and thermal cycling. Hence, even if a stackup could be initially produced with little or no gap 116, provision would have to be made to allow for a gap 116 of varying dimension in the z-axis. Thermal interface materials 114 such as greases or elastomers can be used to fill the gap 116, however, where the gap 116 is large, the thermal interface materials 114 can become sufficiently separated from the surface of the integrated circuit device 102 and the heat sink 110, dramatically reducing it's effective thermal conductivity, or even if such contact is maintained, may be of such low conductivity to make it ineffective for conducting heat sufficiently.

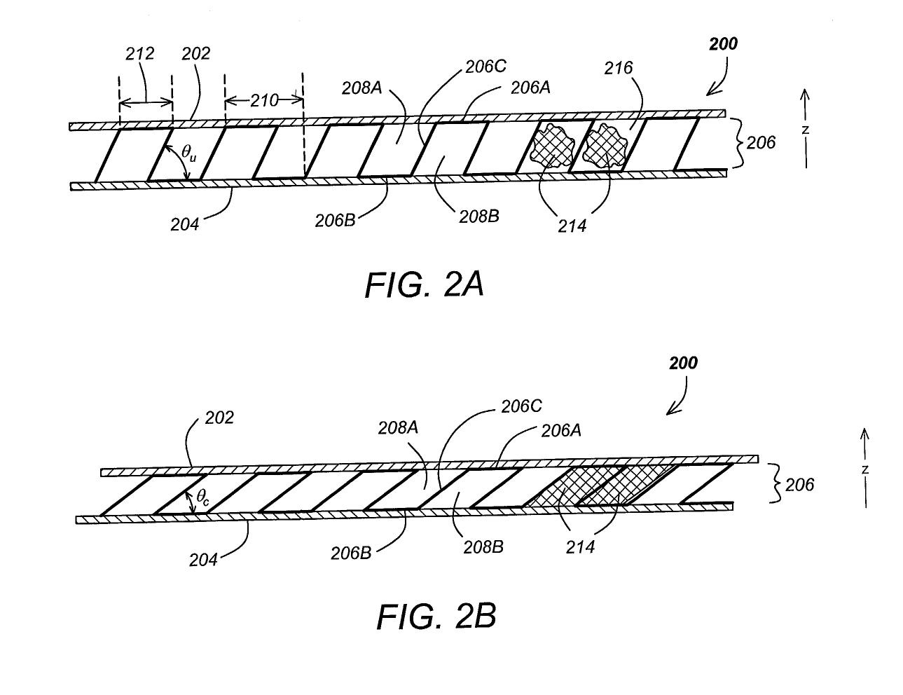

FIGS. 2A and 2B are diagrams depicting one embodiment of the present invention. FIG. 2A shows a heat transfer device 200 (hereinafter alternatively referred to as the “spring beam”) in an uncompressed mode. The heat transfer device 200 comprises a first thermally conductive plate 202 (hereinafter alternatively referred to as the upper plate), a second thermally conductive plate 204 (hereinafter alternatively referred to as the lower plate) and a corrugated member 206 disposed between and in thermal contact with the first thermally conductive plate 202 and the second thermally conductive plate 204. In one embodiment, the corrugated member 206 comprises a metallic construction that bends when placed under compression along the z-axis.

In the illustrated embodiment, the corrugated member 206 is angularly corrugated with a contiguous periodically repeating cross section. The cross section includes a first cross section segment 206A disposed substantially parallel to an in thermal communication with the first thermally conductive plate 202, a second cross section segment 206B substantially parallel to and in thermal communication with the second thermally conductive plate 204, and a third cross section segment 206C communicatively coupled to the first cross section segment 206A and the second cross section segment 206B. A plurality of repeating sections 210 of segments forms the corrugated member 206.

Although a trapezoidal (tilted square wave) pattern is shown in FIG. 2A, other corrugated member 206 cross sections can be utilized as well, including sinusoidal, triangular, or other shape. The optimal shape can be determined from a desired compression spring constant, the total weight to be applied to the heat transfer device 200, the desired thermal resistance, cost, and other parameters. Additionally, the duty cycle of the sections 210 as well as the θ can be varied in a non-symmetric manner to adjust the heat transfer characteristics, channel 216 size, or other parameters as desired.

FIG. 2B is a diagram showing the heat transfer device 200 shown under compression (i.e. with a force applied downward along the z-axis). Note the angle θ formed by the third cross section segment 206C and the thermally is reduced from θᵤ (the “u” subscript denotes “uncompressed”) to θ_{c} (the “c” subscript denotes “compressed”) when the heat transfer device 200 is under compression. Typically, both θᵤ and θ_{c}, are acute angles.

In the illustrated embodiment, a thermal grease or elastomer 214 is disposed in channels 208A and 208B formed by the corrugated member 206. When the heat transfer device 200 is compressed along the z-axis, the cross-sectional area of the channels 208 formed by the corrugated member 206 is reduced, and the thermal grease or elastomer 214 can fill the entire channel with a reduction in the number of pockets 216.

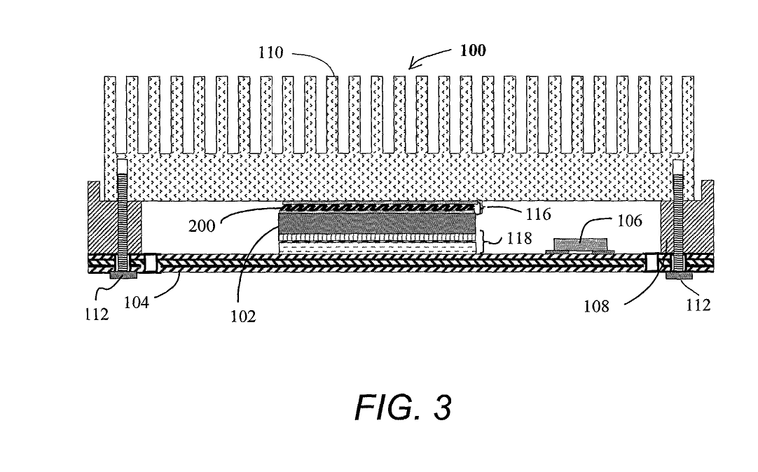

FIG. 3 is a diagram showing the application of the heat transfer device 200 in a stack up assembly 100. The heat transfer device 200 is in the compressed state (similar to that which is shown in FIG. 2B). In one embodiment, when installed, the first thermally conductive plate 202 of the heat transfer device 200 is permanently affixed to a heat sink 110, and the second thermally conductive plate 204 is free to slide along an axis perpendicular to the z-axis when under compression. In this case, the second thermally conductive plate 204 of the heat transfer device 200 compresses and moves to the left (relative to the first thermally conductive plate 202). The resistance to compression is a function of the material used to make the corrugated member, and the number and thickness of the first, second, and third cross sections (206A-206C). As more corrugated member sections 210 per lineal dimension are added and/or the lengths of the third cross section segments 206C of the corrugated member 206 beams shortened, the spring constant of the assembly resisting applied forces in the direction of the z-axis increase significantly. By adjustment of these parameters, the spring constant, maximum compressive load, and thermal resistance of the heat transfer device 200 can be varied as desired. In one embodiment, the corrugated member is comprised of copper or copper alloys.

As can be seen in FIG. 3, one significant advantage of the present invention is that unlike thermal grease and other similar means for transferring heat, the heat transfer device 200 allows a significant force to be applied between the bottom surface of the heat sink 110 and the heat source 102. This force (which is not present in designs that simply use elastomers or thermal greases between the heat source 102 and the bottom surface of the heat sink 110) provides for higher and more predictable thermal conductivity (e.g. since the force contacting the heat source 102 and the heat sink 110 is more predictable than that which can be effected by adjusting screws 112, especially over time and temperature cycling).

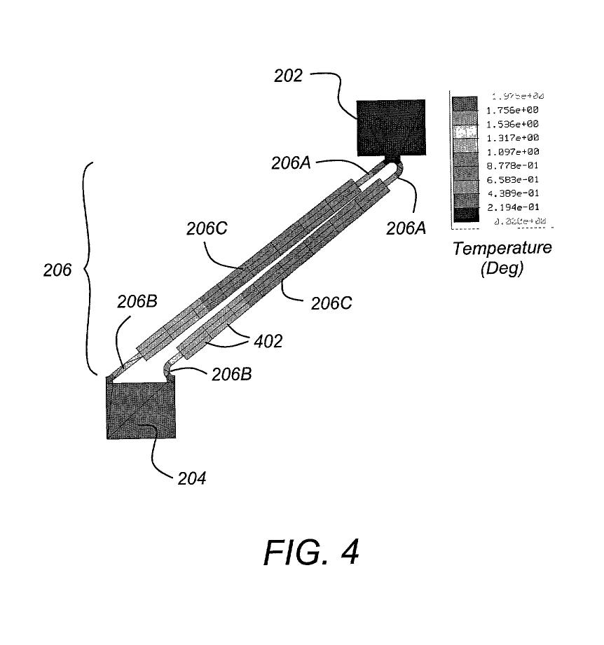

FIG. 4 is a diagram showing a cross-section of another embodiment of the corrugated member 206. This embodiment provides increased thermal conductivity with a lower overall spring constant for compressing the heat transfer device 200 along the z-axis. In this embodiment, the corrugated member 206 is plated with additional material (e.g. copper) 402 in the third cross section segments 206C. This plating can be performed before the corrugated member 206 is bent into shape. This embodiment provides additional thermal conductivity while minimizing any increase in the effective spring constant of the heat transfer device 200. This is because the portions of the corrugated member that provide at least most of such spring resistance in the direction of the z-axis are those portions which bend at the apexes of the angles formed by segments 208A-208C. Before bending the corrugated member 206 into shape, the member would therefore comprise a flat plate having strips of raised copper (which, when bent into shape, would comprise the third cross section segment 206C) in between thinner portions where the bends would take place (which, when bent into shape, would comprise the first cross section segment 206A and the second cross section segment 206B). Lower heat transfer device 200 spring constants can be desirable to prevent damage to the integrated circuit package 102, due to excessively large forces in the z-axis direction or shear forces in a direction perpendicular to the z-axis.

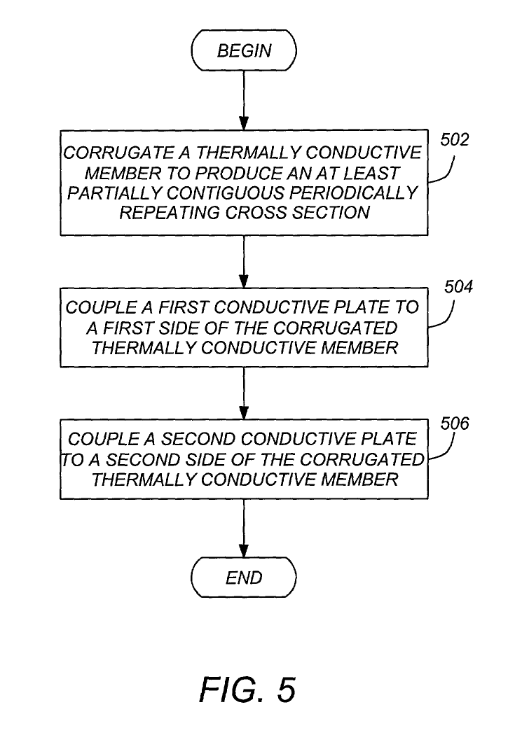

FIG. 5 is a diagram depicting exemplary method steps that can be used to assemble the heat transfer device 200 of the present invention. A thermally conductive member 206 is corrugated 502 to produce an at least partially contiguous periodically repeating cross section. A first conductive plate 202 is coupled 504 to a first side of the corrugated thermally conductive member 206, and a second conductive plate 204 is coupled to a second side of the corrugated thermally conductive member 206.

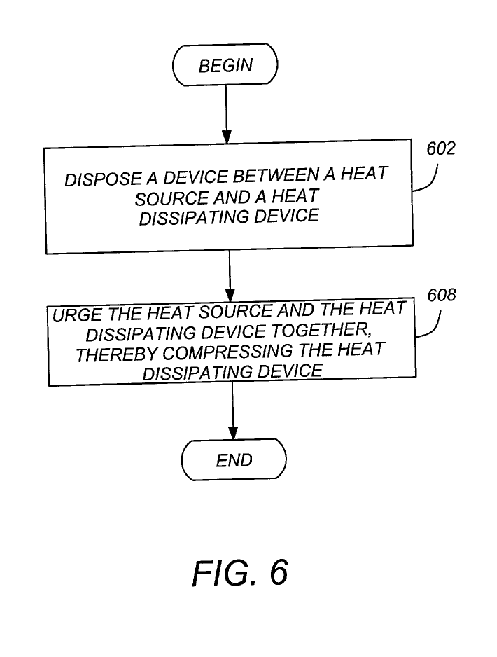

FIG. 6 is a diagram depicting exemplary method steps used to practice a further embodiment of the present invention. A heat transfer device 200 is disposed between a heat source 102 and a heat sink 110. The heat source 102 and the heat sink 110 are urged together thereby compressing the heat dissipating device disposed therebetween. Heat is then transferred from the heat source 102 and the heat sink 110.

### CONCLUSION

This concludes the description of the preferred embodiments of the present invention. In summary, the present invention describes a method, apparatus, and article of manufacture for transferring heat. The apparatus comprises a first thermally conductive plate; a second thermally conductive plate; and an angularly corrugated member disposed between and in thermal communication first thermally conductive plate and the second thermally conductive plate. The angularly corrugated member has a contiguous periodically repeating cross section which includes a first cross section segment, disposable substantially parallel to and in thermal communication with the first thermally conductive plate, a second cross section segment, disposable substantially parallel to and in thermal communication with the second thermally conductive plate, and a third cross section segment, communicatively coupled to the first surface and the second surface, wherein the third cross section segment forming an angle with the first thermally conductive plate.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. An apparatus for transferring heat, comprising:
a first thermally conductive plate;
a second thermally conductive plate; and
a thermally conductive corrugated member disposed between and in thermal communication with the first thermally conductive plate and the second thermally conductive plate, the corrugated member having an at least partially contiguous periodically repeating cross section.

2. The apparatus of claim 1, wherein the corrugated member is compressible in a direction substantially perpendicular to the first thermally conductive plate.

3. The apparatus of claim 1, wherein the corrugated member is angularly corrugated.

4. The apparatus of claim 3, wherein the angularly corrugated member includes:
a first cross section segment, having a portion disposed substantially parallel to and in thermal communication with the first thermally conductive plate;
a second cross section segment, having a portion disposed substantially parallel to and in thermal communication with the second thermally conductive plate;
a third cross section segment, communicatively coupled to the first cross section segment and the second cross section segment, the third cross section segment forming an angle with the first thermally conductive plate.

5. The apparatus of claim 4, wherein the corrugated member is compressible in a direction substantially perpendicular to the first thermally conductive plate, thereby decreasing the angle formed between the first cross section segment and the first thermally conductive plate.

6. The apparatus of claim 4, wherein the angle formed by the third cross section segment and the first thermally conductive plate is an acute angle.

7. The apparatus of claim 6, wherein the angle formed by the third cross section segment and the first thermally conductive is approximately 15 degrees.

8. The apparatus of claim 6, wherein the first thermally conductive plate is substantially perpendicular to the second thermally conductive plate.

9. The apparatus of claim 1, wherein the corrugated member forms a first plurality of grooves open to the first thermally conductive plate and a second plurality of grooves open to the second thermally conductive plate.

10. The apparatus of claim 9, further comprising a thermal interface material disposed within the first plurality of grooves and the second plurality of grooves.

11. The apparatus of claim 1, wherein the corrugated member is formed of beryllium copper.

12. The apparatus of claim 4, wherein the first cross section segment and the second cross section segment are substantially the same length.

13. The apparatus of claim 4, wherein the first cross section segment is bonded to the first thermally conductive plate and the second cross sectional segment is bonded to the second thermally conductive plate.

14. The apparatus of claim 4, wherein the first cross section segment is soldered to the first thermally conductive plate and the second cross section segment is soldered to the second thermally conductive plate.

15. An apparatus for transferring heat from a first surface of a heat source to a first surface of a heat dissipator, comprising:
an angularly corrugated member disposed between and in thermal communication with the first surface of the heat source and the first surface of the heat dissipator, the angularly corrugated member having a contiguous periodically repeating cross section including:
a first cross section segment, disposable substantially parallel to and in thermal communication with the first surface of the heat source;
a second cross section segment, disposable substantially parallel to and in thermal communication with the second heat source;
a third cross section segment, communicatively coupled to the first surface and the second surface, the third cross section segment forming an angle with the first surface of the heat source.

16. The apparatus of claim 15, wherein the angle formed by the third cross section segment and the first surface is an acute angle.

17. The apparatus of claim 16, wherein the angle formed by the third cross section segment and the first surface is approximately 15 degrees.

18. The apparatus of claim 16, wherein the first surface of the heat source is substantially perpendicular to the first surface of the heat dissipator.

19. The apparatus of claim 15, wherein the angularly corrugated member is compressible in a direction substantially perpendicular to the first surface of the heat source, thereby decreasing the angle formed between the first cross section segment and the first surface of the heat source.

20. The apparatus of claim 15, wherein the angularly corrugated member forms a plurality of channels open to the first surface of the heat dissipator and a plurality of channels open to the first surface of the heat source.

21. The apparatus of claim 20, wherein at least some of the channels include a thermal interface material selected from the group comprising thermal grease.

22. The apparatus of claim 15, wherein the angularly corrugated member is formed of beryllium copper.

23. The apparatus of claim 15 wherein the first cross section segment and the second cross section segment are substantially the same length.

24. The apparatus of claim 15 wherein the first cross section segment is bonded to the first surface of the heat source and the second cross sectional segment is bonded to the heat dissipator.

25. The apparatus of claim 24 wherein the first cross section segment is soldered to the first surface of the heat source and the second cross section segment is soldered to the first surface of the heat dissipator.

26. The apparatus of claim 15, further comprising:
a first thermally conductive plate disposed between the first surface of the heat source and the first cross section segment;
a second thermally conductive plate, disposed between the first surface of the heat dissipator and the second cross section segment; and
wherein the first thermally conductive plate is coupled to the first cross section segment, and the second thermally conductive plate is coupled to the second cross section segment.

27. A method of assembling a heat transfer device, comprising the steps of:
corrugating a thermally conductive member to produce a contiguous periodically repeating cross section;
coupling a first conductive plate to a first side of the corrugated thermally conductive member; and
coupling a second conductive plate to a second side of the corrugated thermally conductive member.

28. The method of claim 27, wherein the step of corrugating the thermally conductive member comprises the steps of:
repeatedly bending the thermally conductive member to form a first plurality of channels on a first side of the thermally conductive member and a second plurality of channels on a second side of the thermally conductive member.

29. The method of claim 28, wherein the step of repeatedly bending the thermally conductive member to form a first plurality of channels on a first side of the thermally conductive member and a second plurality of channels on a second side of the thermally conductive member comprises the steps of:
bending the thermally conductive member to form a first cross section segment;
bending the thermally conductive member to form a second cross section segment; and
bending the thermally conductive member to form a third cross section segment.

30. A method of transferring heat from a heat source to a heat dissipating device, comprising the steps of:
disposing a device between the heat source and the heat dissipating device, the device comprising
a first thermally conductive plate;
a second thermally conductive plate; and
a thermally conductive corrugated member disposed between and in thermal communication first thermally conductive plate and the second thermally conductive plate, the corrugated member having an at least partially contiguous periodically repeating cross section; and
compressing the device by urging the heat source and the heat dissipating device together.
